(19) United States
(12) Patent Application Publication
(10) Pub. No.: US 2024/0227173 A1
(43) Pub. Date: Jul. 11, 2024

(54) SYSTEM AND METHOD FOR DESIGNING ROBOT MECHANISMS WITH FLEXIBLE LINKS

(71) Applicants: Disney Enterprises, Inc., Burbank, CA (US); ETH Zürich, Zürich (CH)

(72) Inventors: Moritz Niklaus Bächer, Zürich (CH); Christian Gabriel Schumacher, Aarau (CH); Bernhard Steffen Thomaszewski, Zürich (CH); Lars Espen Knoop, Birmensdorf (CH); Stelian Coros, Zürich (CH); Guirec G.H.F. Maloisel, Zürich (CH)

(21) Appl. No.: 18/093,761

(22) Filed: Jan. 5, 2023

(51) Int. Cl. B25J 9/16; B25J 9/10

(52) U.S. Cl. CPC B25J 9/1605; B25J 9/106

(57) ABSTRACT

An automated design method, and corresponding computer system for implementing such a method and robot mechanism with an optimized flexible link, that is configured to optimize a desired load-displacement behavior of planar flexible-link mechanisms at expected points of interaction. To implement the new design method, a subset of rigid links of an existing rigid-link robot mechanism are replaced with flexible links, optimizing their rest configurations. The efficacy of the design approach has been proven with two fabricated prototypes of robot mechanisms, with one being adapted for grasping tasks and one being adapted for locomotion tasks.

### BACKGROUND

### 1. Field of the Description

The present description relates, in general, to design of link-based robot mechanisms with desired load displacement profiles, and, more particularly, to a system (and associated methods and robots made using such systems and methods) configured for optimally designing flexible-link robot mechanisms having desired load displacement profiles.

### 2. Relevant Background

In conventional robot design, robot mechanisms are designed with rigid links, which allows for a relatively simple control strategy for the robot mechanism. In contrast, compliant mechanisms have the potential to allow robots to be built that can locomote in varied and uncertain terrain or that can include manipulators that can pick up objects of differing shape, weight, or mechanical properties using a single, simple control strategy. In other words, a compliant robot mechanism would have the ability to work throughout a range of, for example, displacements or gripper movements whereas rigid-link mechanisms typically will fail in such applications. To date, however, it remains challenging to design mechanisms that have a desired embodied intelligence, meaning that the right amount of compliance is introduced so that a fixed control strategy remains functional for a user-specified range of interaction-induced forces or displacements.

In compliant mechanism design, a differentiation can be made between mechanisms that are fully compliant and mechanisms that have their compliance concentrated at joints. For the latter, designs are obtained with rigid body replacement methods, which involves substituting flexures for joints. Specific simulation or optimization methods include the Pseudo-Rigid-Body model, the Freedom and Constraint Topologies method, and a rod-based technique that optimizes the shape of flexures after joint substitution. Shape and topology optimization techniques are also common tools to design mechanisms with distributed compliance, avoiding stress concentrations at pseudo-hinge joints. While useful for some robot design applications, prior design efforts have failed to provide optimal compliant mechanism designs.

### SUMMARY

The inventors recognized several deficiencies with prior robot mechanism design approaches. In contrast to prior compliant mechanism design techniques, the inventors propose a design system and method that replaces rigid links with flexible links instead of substituting flexures for joints. The prior shape and topology optimization techniques are not relevant to the new design method because it preserves mechanical joints. Further, prior work on flexible-link mechanisms was limited and differs from the new design method, which optimizes a mechanism's intelligence rather than having to approximate a rigid mechanism's kinematics first.

In brief, the inventors understood that robot mechanisms that exploit compliance can successfully complete complex tasks with uncertainty using simple control strategies. To overcome the difficulty in designing mechanisms with a desired embodied intelligence, an automated design method (and corresponding computer system for implementing such a method) is described herein that is configured to optimize a desired load-displacement behavior of planar flexible-link mechanisms at expected points of interaction. To implement the new design method, a subset of rigid links of an existing rigid-link robot mechanism are replaced with flexible links, optimizing their rest configurations. The efficacy of the design approach has been proven with two fabricated prototypes of robot mechanisms, with one being adapted for grasping tasks and one being adapted for locomotion tasks.

More particularly, a computer-implemented method is provided for optimizing a design of a robot mechanism including a combination of rigid and flexible links. The method includes, with a computing device, receiving user input including a definition of a robot mechanism with a plurality of rigid links, one or more joints coupling the rigid links, and one or more actuators for driving movement of the rigid links. Significantly, the user input further includes a selection of one or more of the rigid links for replacement with flexible links. The method also includes, with a simulator running on the computing device, simulating operation of the robot mechanism with the flexible links and, with an optimizer running on the computing device, comparing the simulated operation of the robot mechanism to user-defined operations of the robot mechanism. Then, based on the comparing, the method involves modifying the shape of the flexible links and optimizing the shape of the flexible links by repeating the simulating and the comparing steps.

In preferred embodiments, the user-defined operations include load-displacement samples for one or more points of interest on the robot mechanism. In such embodiments, the simulating operation includes setting one or more actuators to a particular configuration and forces to user-specified forces in the load-displacement samples. Also, comparing the simulated operation step includes comparing simulated displacements from the simulating operation to user-specified displacements in the load-displacement samples.

In these or other implementations of the method, the definition of the robot mechanism further includes a user selection of a material to be assigned to the flexible link for the simulating operation. It may be useful in some cases for the simulator to take the form of (or include) a differentiable quasi-static simulator. Then, the differentiable quasi-static simulator can be configured to enforce coupling between flexible-flexible and flexible-rigid link pairs in the robot mechanism after inclusion of the flexible links using constraints in a Lagrangian formulation.

Also, in practice, the repeating called out as part of the optimizing step can be performed until the comparing indicates a match between the simulated operation and a load-displacement profile at user-specified points of interest on the robot mechanism. Further, it may be useful for the simulating operation to include performing a smooth remeshing-free parameterization of a volumetric rest shape of the flexible link using splines.

### BRIEF DESCRIPTION OF THE DRAWINGS

FIGS. 1A and 1B illustrate input mechanisms and optimization processes for a design method of the present description to provide an optimal design of a robot mechanism with flexible links;

FIG. 2 illustrates a state representation of a joint between a rigid link and a flexible link that is useful for formulating kinematic constraint between flexible and rigid links of a flexible-link robot mechanism;

FIGS. 3A-3C show three stages of spline-based parameterization for a volumetric link mesh representation of a flexible link according to the present description;

FIGS. 4A-4E are schematic illustrations of a flexible link mesh during the process of optimizing handle transformations;

FIG. 5 illustrates an experimental setup along with fitting results using the experimental setup showing calibration of a Young's modulus value;

FIGS. 6A-6F illustrate a prototyped flexible-link robot mechanism in the form of a compliant claw gripper along with a load-displacement profile used in the design process;

FIGS. 7A-7E illustrate a prototyped flexible-link robot mechanism in the form of a compliant truss gripping finger along with a load-displacement profile used in the design process;

FIGS. 8A-8C illustrate a prototyped flexible-link robot mechanism in the form of a compliant Klann leg along with load-displacement profiles during left, middle, and right point motions of the optimized design; and

FIG. 9 is a functional block diagram of a robot fabrication system with a design system implementing software to provide the simulation and optimization methods or functions described herein.

### DETAILED DESCRIPTION OF THE PREFERRED EMBODIMENTS

Briefly, the following description describes a design method (and associate system with a simulator and an optimizer for computer-assisted design) configured for optimal design of flexible-link mechanisms with desired load-displacement profiles. In the design method, a subset of rigid links of a planar mechanism (provided as user input in the method) are replaced with flexible links. The method involves optimizing the rest shapes of the flexible links so that a user-specified force-displacement behavior at expected points of interaction can be achieved as closely as possible.

In contrast to work on compliant mechanism design, the method also involves introduction of compliance in links instead of joints while keeping the control strategy fixed. This provides several advantages. First, the flexible-link robot mechanism maintains its kinematic behavior if no interaction forces are applied. The design space can, therefore, be used to achieve a desired distribution of compliance instead of recovering a kinematic behavior first. Second, the no-interaction behavior can be used as a starting point for users to specify a desired load-displacement behavior at a set of points of interest.

The method is computer implemented to automate the design with a combination of a simulator algorithm or routine and a differentiable simulator algorithm or routine (or, more simply, a “simulator” and an “optimizer”). More specifically, a differentiable quasi-static simulator is provided for flexible link mechanisms, and the simulator is configured for enforcing the coupling between flexible-flexible link pairs and flexible-rigid link pairs (and, also, mechanical joints) with constraints, for example, in a Lagrangian formulation. A design optimizer (or optimization algorithm or module) is provided that is configured to achieve a desired load-displacement profile at user-specified points of interest. The design optimizer is further configured to leverage sensitivity analysis to compute derivatives of simulation states with respect to design parameters. The method may also provide a smooth remeshing-free parameterization of the volumetric rest shape of flexible links such as by using splines and an extension of the Bounded Biharmonic Weights technique by Jacobson et al. (i.e., A. Jacobson et al., “Bounded biharmonic weights for real-time deformation” available in ACM Trans. Graph., vol. 30, no. 4, July 2022, which is incorporated herein by reference). The utility of the new design method is provided with a set of demonstrations that include two fabricated examples involving automated design of manipulators and soft robotic components with applications in grasping and locomotion.

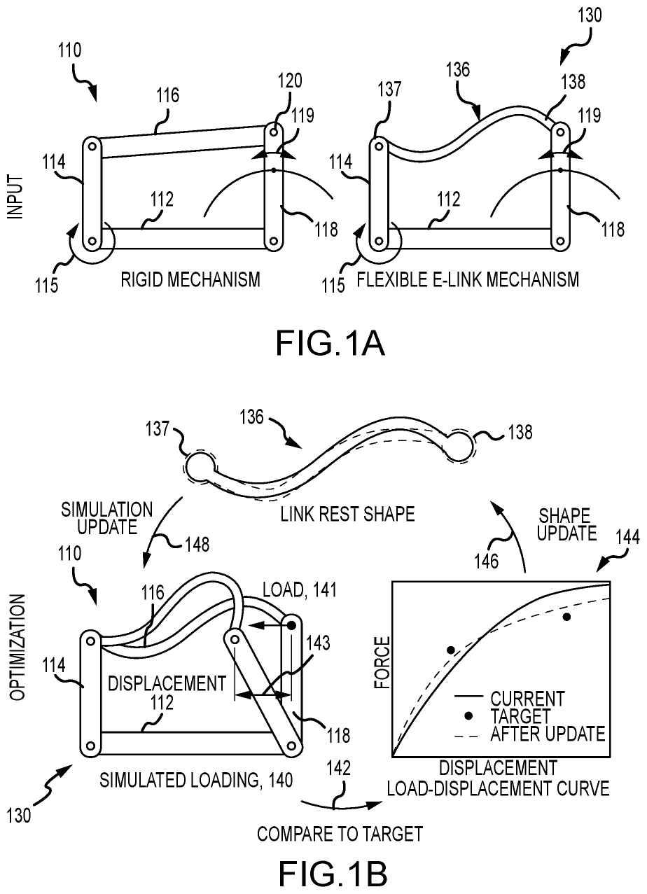

The design method takes as input, from a user of the design system, a functional rigid-link mechanism (or rigid robot mechanism). FIGS. 1A and 1B illustrate input mechanisms 110 and 130 and optimization processes for a design method of the present description to provide an optimal design of a robot mechanism 130 with a flexible link 136. As shown, a user provides a definition or model of a rigid mechanism 110, with this example showing a four-bar linkage or mechanism 110 with rigid links 112, 114, 116, and 118. A control strategy is also input that provides for pivoting as shown at 115 of link 114 and displacement 119 of a point of interest 120 on link 118.

As shown in FIG. 1A, the user input further includes the user's selection of a rigid link 116 in the input mechanism 110 that is to be replaced with a flexible link 136, which is coupled at its ends 137 and 138 to the ends of rigid links 114 and 118. Stated differently, flexible-link robot mechanism 130 is a kinematically equivalent and compliant version of the mechanism 110, where a subset of links (i.e., link 116) is replaced with flexible components (i.e., link 136).

FIG. 1B illustrates aspects of the optimization process in which the user provides input in the form of a load/force 141 and displacement 119 pair for link 118 during operation under the input control strategy for mechanism 110. Loading is simulated at 140 with the flexible link 136, and the results (load 141 and displacement 143) with the present rest shape of the flexible link 136 (as shown at the top of FIG. 1B) is compared 142 to the target, with the resulting load-displacement curve 144 provided in FIG. 1B. The shape 136 is then updated 146 in the optimization process to provide a changed or updated rest shape for link 136, and then the simulation is updated 148 to provide an updated simulated loading 140 with the changed flexible link 136. At each iteration, the simulator of the design system updates the mechanism state under prescribed external loads, given the current link design (see simulated loading 140 in FIG. 1B). The optimizer of the design system then computes the error with respect to target force-displacement pairs and, in response, updates the rest shape of the flexible link 136 using derivatives of the state with respect to design parameters (see curve 144 in FIG. 1B).

To ease this description, planar mechanisms are described in detail, with the understanding that the simulation and optimization processes taught are more generally applicable to 3D mechanisms. To avoid out-of-plane deformations, the thickness of the flexible links can be set to a sufficiently large value. The user then can be allowed and/or requested to select a subset of links in the rigid-link robot mechanism that should be made compliant and assign a material to each. The links may be assumed to be sufficiently stiff such that a quasi-static model may be sufficient in the design method. Under this assumption, the kinematic behavior of the flexible-link robot mechanism is preserved if no external or body forces are acting on the components or they have a negligible effect. The reason for this result is that flexible links, independent of their geometry, do not flex if no forces are present. The only constraint is that the joint locations should be preserved.

The response of the flexible-link robot mechanism 130 to external perturbations is now a function of the rest shape of the flexible links. Using a differentiable simulation, shown at 140 and described in more detail below, the load-displacement behavior can be predicted at a single or at several configurations of interest (e.g., at user-selected point of interest 120 on link 118). Here, the term “configuration” is used to refer to a set of position values of the actuators that remain unchanged during optimization. Therefore, the control policy or strategy for the robot mechanism is kept unchanged or fixed from mechanism 110 to mechanism 130, and the mechanism's embodiment is the only parameter that is optimized. With analytical derivatives of simulation states with respect to design parameters, the method can then iteratively optimize the load-displacement behavior (see graph or curve 144 in FIG. 1B), and such optimization is described below in further detail with reference to a gripper in its closed configuration. As part of the design method, the user specifies a target load-displacement behavior or pair for each configuration of interest with a set of load-displacement sample points that are used by the optimizer for optimization (again, see the load-displacement curve 144 of FIG. 1B).

To simulate flexible-link robot mechanisms, the simulator is configured to use or rely upon a quasi-static model. Setting the motors to a prescribed position, the static equilibrium of rigid and flexible components is solved for under mechanical joint constraints and external forces:

$$\begin{matrix}{min}_{s} E ( s ) & s . t . C ( s ) = 0\end{matrix} \qquad Eq . ( 1 )$$

where s is the state of the mechanism, E the total potential energy, and C the vector of kinematic constraints. The energy E sums up the internal energy of all deformed flexible components, subtracting the work that external forces perform on the mechanism. The state vector, the energy, and the constraints are discussed in more detail below.

The constrained minimization problem of Eq. (1) is solved by forming the Lagrangian:

$$ℒ ( s , λ ) = E ( s ) - {λ}^{T} C ( s ) \qquad Eq . ( 2 )$$

with Lagrange multipliers 1. In one useful implementation, a standard Augmented Lagrangian Method may be used.

Note that this formulation is general and is not restricted to planar robot mechanisms nor to the specific flexible-link robot mechanisms used as examples in this description. As such, the simulator (and simulation method(s)) can handle arbitrary flexible multibody systems that include rigid and flexible bodies whose relative motion is restricted by mechanical joints of varying degrees of freedom. Moreover, the simulator (and simulation method(s)) can be used to check if there is no out-of-plane buckling behavior.

With regard to mechanism state representation, the state vector, s, is formed by the concatenation of the degrees of freedom (DoFs) of the different rigid and flexible links. Rigid links contribute 6 DoFs (i.e., 3D position and orientation). In practice, rigid body rotations can be formulated as unit quaternions so that rigid links are parameterized by a 7-vector. A corresponding constraint that enforces quaternions to remain unit length can be appended to the vector C.

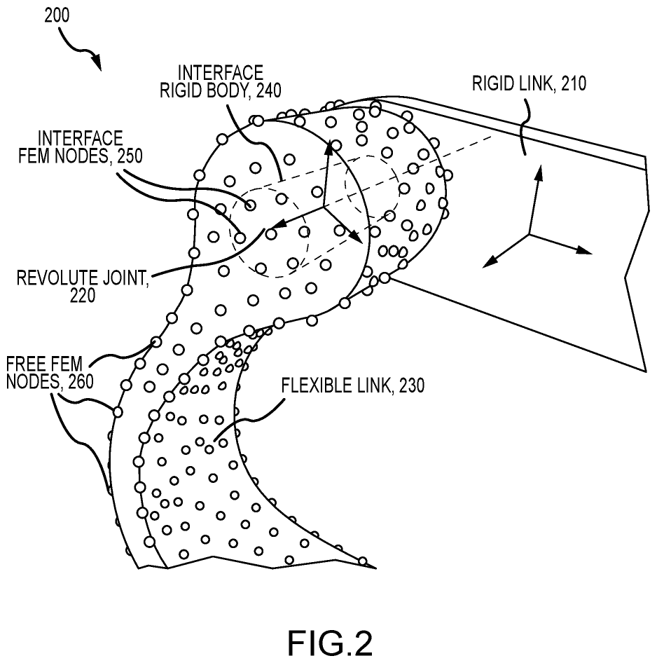

The degrees of freedom of flexible links are defined by their finite-element (FE) discretization (i.e., 3 DoFs per FE node) and also are appended to vector s. However, to model the behavior of mechanical joints, such as a hinge, interface rigid bodies may be defined by collecting all FE nodes within a volume that is defined by the DoFs of a joint. This can be seen with reference to FIG. 2 that illustrates a portion of flexible-link robot mechanism 200 that includes a rigid link 210 coupled to a flexible link 230 via revolute joint 220. In this modeling of mechanism 200, an interface rigid body 240 is shown along with interface and free FEM nodes 250 and 260.

FIG. 2 is useful for showing the FE nodes within a volume that is defined by a joint's DOF collectively from an interface rigid body 240 that enables one to formulate kinematic constraints between a flexible link 230 and a rigid link 210. The set of FE nodes is constrained to move rigidly and is used to implement mechanical joint constraints between neighboring pairs of flexible and rigid bodies as well as between pairs of flexible bodies. These FE nodes can then be omitted, adding a 7-vector for the DoFs of the interface rigid body instead to vector s.

To formulate kinematic constraints, C, for joints and actuators, a variety of approaches may be used such as the technique described in C. Schumacher et al., “A versatile inverse kinematics formulation for retargeting motions onto robots with kinematic loops,” IEEE Robotics and Automation Letters, vol. 6, no. 2, pp. 943-950, 2021, which is incorporated herein by reference. To formulate constraints between pairs of flexible-flexible and flexible-rigid links, constraints may be introduced that restrict the relative motion of the states of the respective interface and standard rigid bodies.

With regards to total potential energy, the total potential energy can be thought of as including two terms as shown by:

$$E = {E}_{i n t} - {E}_{e x t} \qquad Eq . ( 3 )$$

The elastic energy, Eᵢₙₜ, sums up the internal energy of all the deformed finite elements the flexible links are made of, numerically integrating a standard strain energy density over the elements' volumes. For many materials (including those used in the exemplary models herein), a Neohookean model is sufficient. Note that interface rigid bodies, while viewed as rigid bodies in the formulation of the state and constraints, are made up of FEM nodes and, therefore also contribute to Eᵢₙₜ, implementing the coupling between rigid and flexible bodies.

From the elastic energy, the work that external forces perform can be subtracted by summing up 3D forces, f_{f}, that act at fixed positions, P_{f}(s), on the mechanism, times the displacement:

$${E}_{e x t} = {Σ}_{f o rces f} {f}_{f}^{T} {p}_{f} ( s ) \qquad Eq . ( 4 )$$

omitting the constant term (i.e., force times initial position). To compute the position pf, a rigid body transformation can be applied to a fixed location in rigid body coordinates, or an FE interpolation for fixed positions on flexible bodies may be performed.

At this point in the description, it may be useful to describe in greater detail the operations of the optimizer (or optimization steps/processes) to optimize the load-displacement behavior. The input to the design optimization module or optimizer is a set of configurations, which are uniquely defined by a set of position values for all actuators, that remain fixed during optimizations. For each configuration, the user specifies load-displacement samples for points of interest on the robot mechanism. Setting the actuators to a particular configuration i, and the forces to the user-specified values for sample j, the performance of the current design can be evaluated by comparing simulated displacements dᵢⱼ to specified displacements dᵢⱼ:

$$O ( p ) = {Σ}_{config . i} {Σ}_{sample j \frac{1}{2}} {‖ {d}_{i j} ( {s}_{i j} ( p ) ) - {\overline{d}}_{i j} ‖}^{2} + ℛ ( p ) \qquad Eq . ( 5 )$$

where [symbol] (p) is a regularization term that we describe in more detail below.

In some implementations of the optimization process, the performance of a mechanism design is only evaluated at a sparse set of configurations and force-displacement samples. This is sufficient as long as it can be assumed that the quasi-static state of a mechanism is not path dependent. For multi-stable mechanism design, the control strategy can be sampled more finely, simulating the state of the mechanism for the entire path and then choosing a subset of configurations i for performance evaluation.

With regard to regularization, it may be desirable to ensure that the mesh quality of the flexible components remains sufficiently high to preserve the accuracy of the simulator and avoid numerical stiffening. To this end, the regularization term:

$${ℛ}_{m e s h} ( p ) = {Σ}_{e l e ment e} β ( ρ ( e ) ) \qquad Eq . ( 6 )$$

to the objective, penalizing elements with low-quality rest shape. Here, p measures the aspect ratio of an element, and β is a C² barrier function that prevents too large aspect ratios. For tetrahedral elements, the ratio between the circumradius and the radius of an inscribed sphere is a measure with desirable properties, e.g., among alternatives this metric has the advantage of being differentiable (with no min or max operator) with respect to the vertices of a tetrahedron. Furthermore, the element inversions (i.e., elements with negative volume) can be monitored at all optimization steps, backtracking if any inversions are detected by setting [symbol] mesh to infinity.

As discussed in more detail below, a spline-based parameterization may be used that defines the centerline of links and the local thickness. To limit the search space to non-degenerate link shapes and to ensure fabricability, an additional regularization term [symbol] shape can be introduced or used. This second regularizer prevents links from crossing a maximal curvature bound and from becoming too thin or too thick. To bound the local curvature, the spline can be sampled and the ratio,

$$r = \frac{h}{R} ,$$

bound for every three consecutive samples, where h is the average segment length between samples and R is the circumradius of the three samples (R=∞ and r=0 for samples on a line). To bound the in-plane thickness along the spline, the interpolated thickness can be penalized at sample points. To implement these penalties, the same barrier function may be used as was used in the mesh quality regularizer.

Finally, to ensure that the design problem is bounded, the design parameters are asked to remain close to their initial values p^{init}:

$${ℛ}_{i n i t} ( p ) = \frac{1}{2} {‖ p - {p}^{i n i t} ‖}^{2} \qquad Eq . ( 7 )$$

To solve this problem using gradient-based optimization, it is useful to take derivatives of the implicit function, s(p), defined by the force equilibrium equation, or equivalently by first-order optimality of the forward simulation:

$$\frac{\partial ℒ}{\partial y} ( y , p ) = 0 \qquad Eq . ( 8 )$$

in which y refers to the concatenation s|λ. To do so, one can rely on sensitivity analysis and then applying the implicit function theorem to Eq. (8) yields the derivatives:

$$\frac{dy}{d p} = - {( \frac{{\partial }^{2} ℒ}{\partial {y}^{2}} )}^{- 1} \frac{{\partial }^{2} ℒ}{\partial y \partial p} \qquad Eq . ( 9 )$$

from which can be extracted the desired ds/dp. By applying the chain rule, one can obtain the objective gradient:

$$\frac{dO}{d p} = {\sum }_{i , j} \frac{\partial {O}_{i j}}{\partial {s}_{i j}} \frac{d {s}_{i j}}{d p} + \frac{d ℛ}{d p}$$

with objectives

$${O}_{i j} = \frac{1}{2} {‖ {d}_{i j} ( {s}_{i j} ( p ) ) - {\overline{d}}_{i j} ‖}^{2} .$$

The optimal design parameters can then be computed using standard quasi-Newton (BFGS) minimization.

In the following paragraphs, a description is provided of one useful approach to parameterizing the rest shape of flexible links, which provides design parameters for optimization. This may be considered a remeshing-free shape parameterization. The description focuses on a single link for ease of explanation. The parameterization is formulated to fulfill requirements of differentiability, mesh quality, and joint interface preservation. As to differentiability, changes to the connectivity of a volumetric mesh are discontinuous operations and, therefore, are ill-suited for design optimization. Hence, the inventors required that the parameterization be configured or performed to preserve the connectivity. Regarding mesh quality, a candidate parameterization preferably keeps the quality of elements sufficiently high for a wide range of design parameters. To preserve joint interfaces, nodes that represent the interface to a neighboring rigid or flexible link preferably remain unchanged, except for undergoing a rigid body transformation that the degrees of freedom of the joint allow.

Because links are relatively slender, a natural choice are splines. Routed along the centerline of a link, a few cubic Hermite spline segments provide sufficient control of a link's overall shape while keeping the parameter count small. However, it is non-trivial to map changes of curves to changes of a volumetric mesh, fulfilling the above list of requirements at the same time. To define this mapping, one can rely on Bounded Biharmonic Weights (BBW). First, it may be useful to define a set of handles whose degrees of freedom are controlled by splines. These handles then propagate the design changes to the mesh nodes of a link's rest configuration. A key advantage of using BBW is the C^{∞} smoothness of the mapping as long as mesh nodes are not co-located with handles. Moreover, BBW interfaces with a versatile set of handle types and enable the specification of custom parameterizations, which could help extend the parameterization to optimize spatial mechanisms.

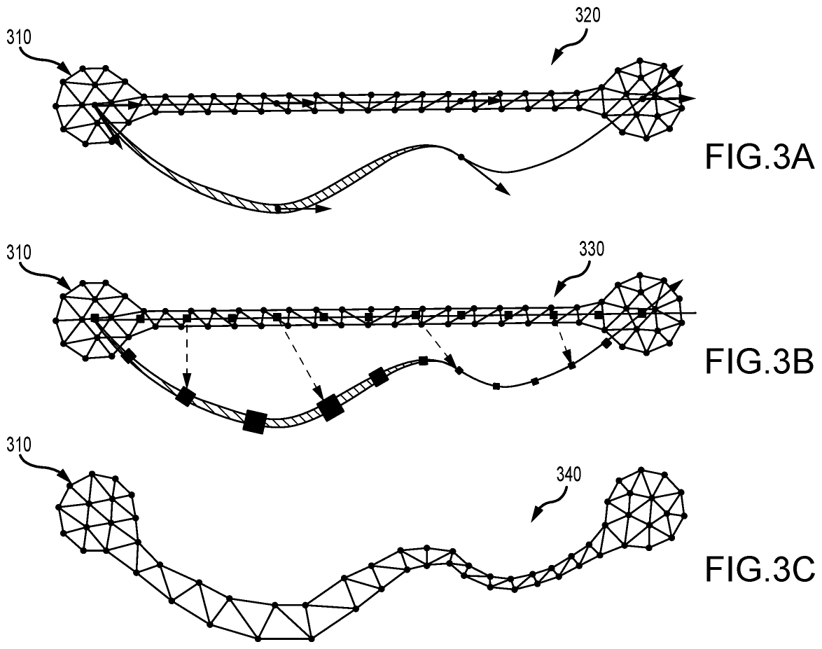

With regard to performing spline-based parameterization, each flexible link can be assumed to be volumetrically meshed in the mechanism's rest post. To define this parameterization, a set of cubic Hermite spline segments can be initialized that are routed along the centerline. This can be seen in FIGS. 3A-3C, which show a flexible link 310 during initialization 310 of spline segments, during design optimizations 320, and with produced quality segments at 330, respectively. In FIG. 3A, the cubic Hermite spline segments are initialized 320 along the centerline of the volumetric link mesh representation of the flexible link 310 (shown in 2D for simplicity). Design optimizations at 330 then change their control points that are propagated using BBW handles as shown at 330 in FIG. 3B, with distribution uniform along the spline so as to result in a link mesh with high quality elements as shown at 340 in FIG. 3C. Constrained regions can typically only undergo rigid body transformations that the mechanical joint DoFs allow.

To perform the initialization step, a control point can be co-located with each mechanical joint and additional control points can be placed on the approximate centerline. Then, in-plane tangent vectors are initialized so that the spline representation approximates the centerline well. While 2D splines with two position and two tangent parameters per control point suffice for parameterization of a link's centerline, they do not allow one to vary the local thickness of a link. To parameterize the thickness, the z-components of the position and tangent vector of 3D-spline control points can be used. In this regard, the local thickness can be initialized to one, and the corresponding tangent vector component can be initialized to zero (for all control points). A value of one, in this regard, means that the local thickness is unchanged.

The design parameters p that are changed during parameterizations are 3D positions and 3D tangents of all control points, excluding the 3D position parameters of control points at mechanical joints to preserve their rest configuration positions and the local thickness. The mapping of design parameters to an interpolated position and tangent at the location t along the spline is therefore given as:

$$p , t ↦ [ \begin{matrix}x ( p , t ) \\ δ ( p , t )\end{matrix} ] and p , t ↦ [ \begin{matrix}t ( p , t ) \\ \dot{δ} ( p , t )\end{matrix} ] \qquad Eq . ( 10 )$$

where δ is the local thickness at point x∈ [symbol] ², and t∈ [symbol] ² is the corresponding tangent. Because the local thickness, δ, is set to one and its derivative, \dot{δ}, to zero in p^{init}, the local thickness is one and, therefore, unchanged everywhere along the spline at the start of a design optimization.

To propagate changes of design parameters to a link's simulation mesh, the spline is uniformly sampled, creating joint handles at mechanical joints and intermediary handles at regular arc-length intervals along the spline (see mesh 310 during parameterization step 330 of FIG. 3B). Then, the BBW weights wᵢⱼ can be computed that define the mapping of mesh nodes vᵢ^{int} ∈ [symbol] ³ to their new rest pose position vᵢ ∈ [symbol] ³:

$${v}_{i} = {\sum }_{h a ndle j} {w}_{ij} T ( p , {t}_{j} ; {v}_{i}^{i n i t} ) \qquad Eq . ( 11 )$$

by transforming their initial homogeneous coordinates with a 3×4 affine transformation matrix:

$$T ( p , {t}_{j} ; {v}_{i}^{i n i t} ) = [ \begin{matrix}{δ}_{j} {{R}_{j} ( {R}_{i}^{i n i t} )}^{T} & 0 & {x}_{j} - {x}_{j}^{i n i t} \\ {0}^{T} & 1 & 0\end{matrix} ] [ \begin{matrix}{v}_{i}^{i n i t} \\ 1\end{matrix} ]$$

where the initial and current 2D positions and rotations, R, of handle j are evaluated at (p^{init}, tⱼ^{int}) and (p, tⱼ), respectively.

The weights are computed, such as taught in Jacobsen et al., “Bounded biharmonic weights for real-time deformation,” ACM Trans. Graph., vol. 30, no. 4, July 2011, which is incorporated herein by reference, with the following extensions. The interface nodes around a joint are constrained to share equal weights. As BBW handles should be co-located with mesh vertices, the mesh is preferably expanded so that it contains all handles, with new vertices being disregarded when extracting the deformed shape. Besides the Laplacian energy, the squared out-of-plane gradient of the weights is minimized to keep the deformation as uniform as possible along a link's depth.

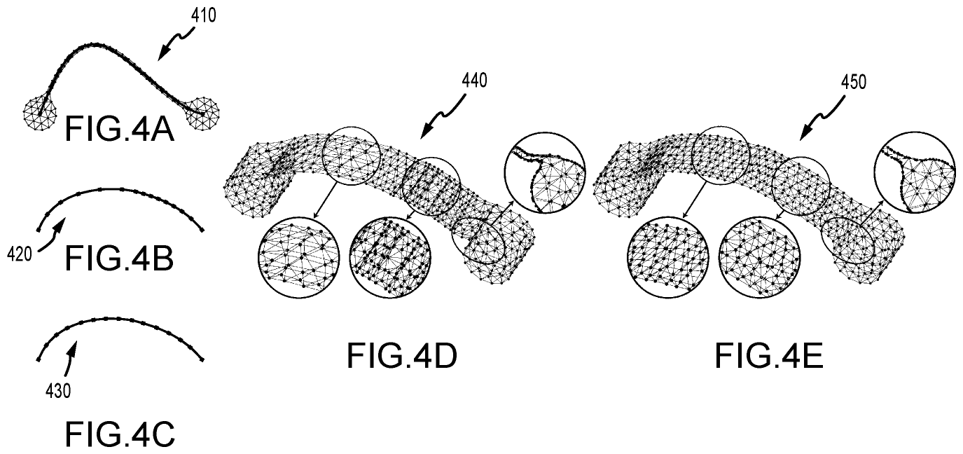

FIGS. 4A-4E illustrate schematically a flexible link 410-450 during the process of optimizing handle transformations. More specifically, FIG. 4A shows a side view of an input mesh 410 with splines with handles and with constrained vertices. FIG. 4B shows a naïve handle mapping 420 of the link 410 with tⱼ=tⱼ^{int} and aⱼ prescribed by the spline tangents of joint handles. At 430 in FIG. 4C, results of optimized mapping are shown. FIGS. 4D and 4E shown resulting deformed meshes with mesh 440 being naïve and mesh 450 being optimized, with good and bad mesh quality indicated (in practice) with coloring of vertices (not shown in FIGS. 4D and 4E for simplicity). By letting intermediary handles “slide” along the spline undesirable stretching or compression is avoided as shown at details A and B of FIGS. 4D and 4E. By letting joint handles rotate, smoother transitions are obtained with the middle section as shown at detail C of FIGS. 4D and 4E.

While it may be natural to keep handles at the same locations on a spline (or, in other words, to set tⱼ=tⱼ^{int}), this choice can lead to many low-quality elements that can restrict the range of design parameters, as one can see in FIG. 4D. An effective strategy to mitigate this problem is to let joint handles rotate and intermediary handles “slide” along the spline. To do so, one can solve for either an angle parameter aⱼ that defines the 2D rotation Rⱼ at a joint or the location tⱼ along the spline (intermediary handle) that minimize the aspect ratio p of all elements after updating the design parameters p:

$${min}_{θ} {Σ}_{e l e m ents e} ρ ( θ , p ; e ) \qquad Eq . ( 12 )$$

with variable vector entries θⱼ=aⱼ or tⱼ as appropriate (one variable per handle).

Before evaluating the objective or objective gradient of the design optimization for a new set of parameters, the above problem is solved to identify the optimal handle locations. Then, the total derivative of finite element degrees of freedom can be computed in the state vector s by applying the chain rule:

$$\frac{d {v}_{i}}{d p} = {\sum }_{handle j} {w}_{ij} ( \frac{\partial {T}_{j}}{\partial p} + \frac{\partial {T}_{j}}{\partial {θ}_{j}} \frac{d {θ}_{j}}{d p} ) \qquad Eq . ( 13 )$$

and the implicit function theorem:

$$\frac{d θ}{d p} = - {( \frac{{\partial }^{2} ( {Σ}_{e} ρ ( e ) )}{\partial {θ}^{2}} )}^{- 1} \frac{{\partial }^{2} ( {Σ}_{e} ρ ( e ) )}{\partial θ \partial p} \qquad Eq . ( 14 )$$

The inventors tested the above processes and achieved desirable and useful results. The following description presents several applications of the design method in practice to grasping and locomotion problems in robot mechanism design. In each case, the optimizer was able to produce a design satisfying the user requirements (or inputs), which were set using simple heuristics according to the problem at hand. To illustrate the transfer of the simulations to the real world, the inventors fabricated and tested two prototypes, with one proving usefulness in addressing locomotion over uneven surfaces and the other for gripping items within a range of sizes and/or softness.

In these prototypes, the flexible links were fabricated of one of two materials. Particularly, the flexible links were made of Smooth-Sil 950 silicone using injection molding into 3D-printed molds or of Onyx (i.e., carbon-filled nylon) using a Markforged X7 printer. Onyx parts were left to stabilize for forty-eight hours before use to ensure consistent material properties. The rigid links of the robot mechanisms were 3D printed in Onyx with a significantly larger in-plane thickness. For revolute joints of the robot mechanisms, 3-millimeter pins and press-fitted polymer bearings were used.

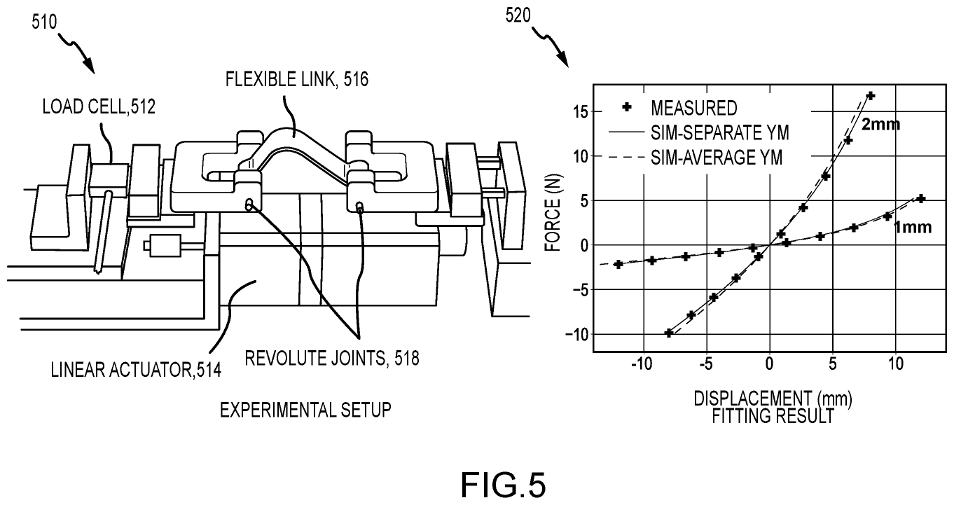

Further with regard to material parameters, flexible links were simulated using tetrahedral elements of order 2 and a hyperelastic Neohookean model. Poisson's ratio and Young's modulus were set to 0.475 and 1.90 MPa for silicone and 0.42 and 1.77 GPa for Onyx, respectively. The value for Young's modulus was calibrated with a characterization experiment as illustrated with reference to FIG. 5 for Onyx. As shown in FIG. 5, the experimental setup 510 included a load cell 512, a linear actuator 514, a flexible link 516, and revolute joints 518, and the fitting results achieved are shown in graph 520. In this experiment with setup 510, two sample links, with 1 mm and 2 mm in-plane thickness and formed of Onyx material were tested to provide Young's modulus fitting. The graph 520 shows a plot of simulated forces with Young's modulus set as resulting from the separate fit for each sample (e.g., with the curves in graph 520 showing 1.89 GPa/1.65 GPa for the 1 mm/2 mm samples and with a final average of 1.77 GPa for both samples). More specifically, the optimizer described herein was used as discussed above but replacing shape design variables with Young's modulus to match force-displacement pairs in the captured data. The optimal moduli obtained for material examples of different thicknesses were then averaged.

As a first demonstration of the design method, the method was used to optimize an Onyx, compliant (or flexible), claw-like gripper that was configured for closing on an object with simple open-loop controller (which implemented a control strategy defined for a rigid-link robot mechanism). The goal in the design process was to provide robust grasping over a range of object sizes rather than for a single size. More specifically, the grasping force should remain within user-specified minimum and maximum bounds, for a prescribed range of object sizes. This translates into two targets for the optimizer described herein: (1) the displacement of the end effector perpendicularly to the object (in a closed configuration) must match the smallest or largest object size (5 and 20 mm in this example) when (2) the minimal or maximal force is applied (4 and 10 N in this example). For a symmetric design, the inventors ran the design process or pipeline on half of the gripper only.

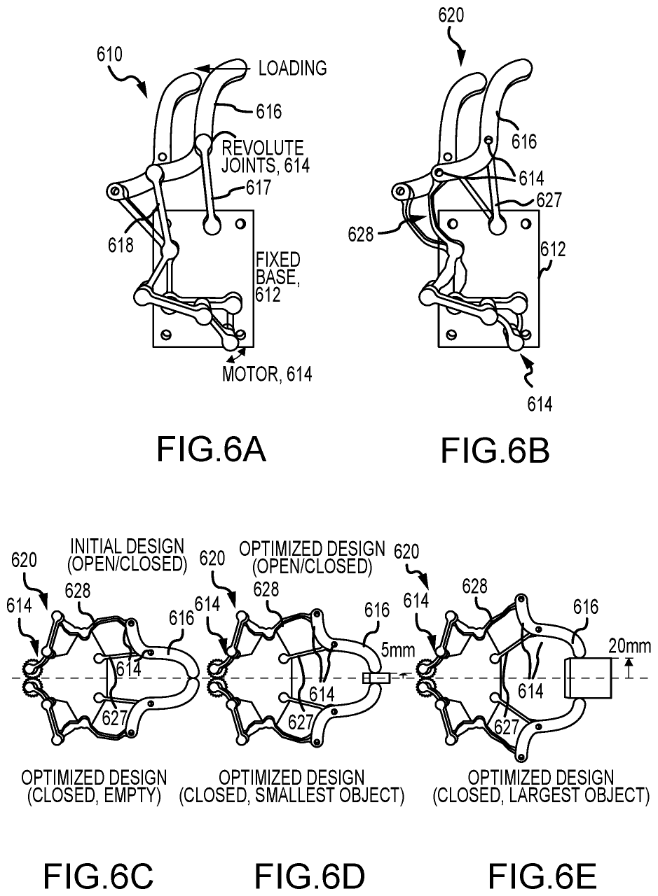

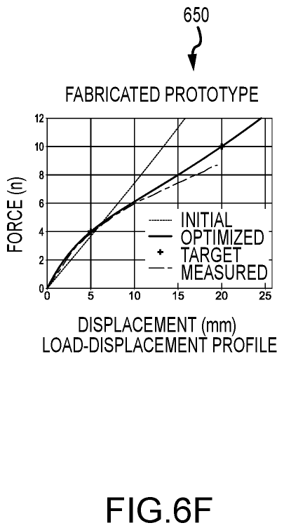

FIGS. 6A-6F illustrate a prototyped flexible-link mechanism in the form of a compliant claw gripper along with a load-displacement profile used in the design process. Particularly, FIG. 6A illustrates a rigid-link robot mechanism (gripper) 610 that includes a fixed and rigid base 612, a motor/driver 614, rigid links 616, 617, and 618, and revolute joints between the links 616-618. A control strategy is defined for the mechanism 610 that includes operation of the motor 614 as well as load-displacement pairs for one or more points of interest. The user has selected to replace rigid links 617 and 618 with flexible links 627 and 628 (which is the design space), and FIGS. 6B-6E show the optimized design for the link 628 with the flexible-link robot mechanism 620 in the open/closed position, the closed and empty position, the closed with smallest object position, and the closed with largest object position while FIG. 6F provides a graph 650 showing the load-displacement profile for the mechanisms 610 and 620 initially and during the design and test process. The load-displacement curves of graph 650 were computed using the simulator described herein on the initial and optimized design of the mechanism 610 and 620 and also as measured on a prototype fabricated based on the optimized design 620.

As shown in FIG. 6F, the load-displacement profile matches the targets on the optimized design 620. It is of interest that the resulting profile is non-linear, which could not be obtained with a linear spring in series with the end effector 616. Note also that, in this example as well others, the compliance is obtained using only the mechanical structure with the end effector 616 being made rigid to better identify the contribution of the new design method taught herein. In practice, the newly designed flexible links 627 and 628 could be combined with a soft finger pad for better object shape adaptation. A prototype (half-) gripper, on which force-displacement data was captured, was fabricated according to the design of mechanism 620 and using a setting similar to the material characterization experiments discussed above. For simplicity, the gripper was directly fabricated in closed configuration. A good agreement was found between the simulations and reality, with some error in the large displacements region that may be due to the flexible links exploiting the slight out-of-plane compliance in the revolute joints to deflect less.

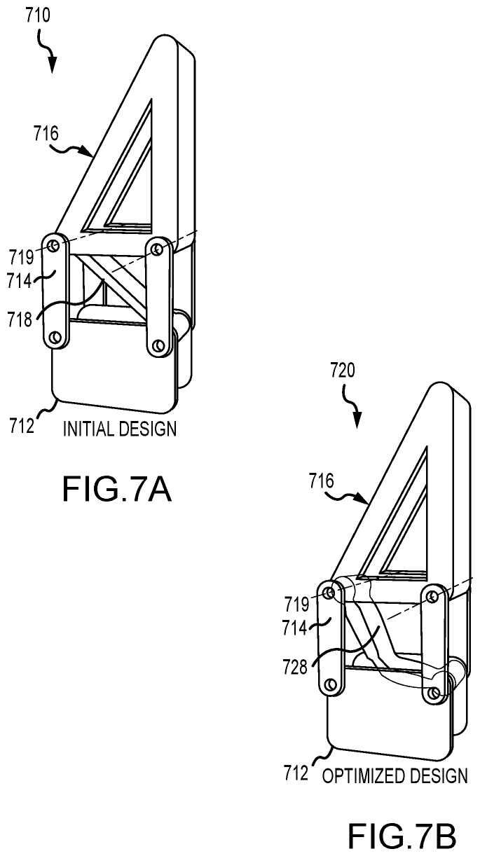

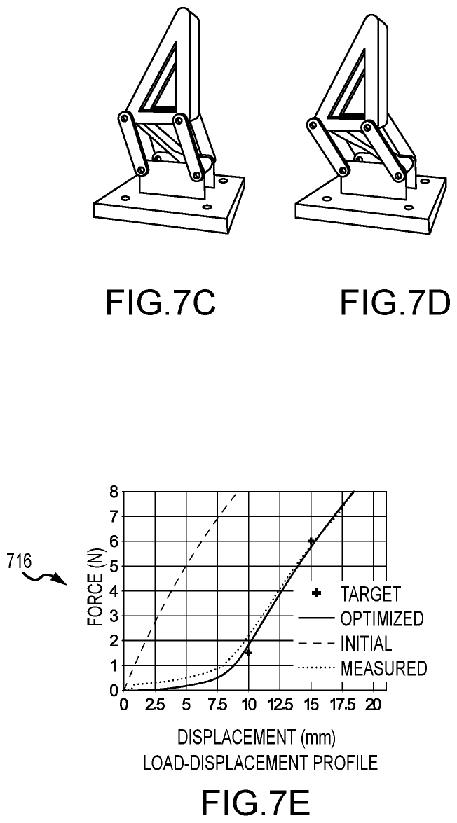

In another test for the new design method and system, the inventors designed a gripper finger for a parallel-jaw gripper by augmenting a truss structure with a flexible silicone link so that the finger deforms in contact with the grasped object. FIG. 7A shows the initial design of this rigid-link robot mechanism 710, which includes a fixed (or rigid) base 712, rigid links 714, 716, and 718, and revolute joints 719 coupling the links 714, 716, and 718. To provide a flexible-link robot mechanism 720 (shown in FIGS. 7B and under loading conditions in FIGS. 7C and 7D), rigid link 718 is replaced with flexible link 728, and a user-specified load-displacement profile is also provided as input for use in the optimization of link 728 (with graph 760 showing the target profile as well as the initial, optimized, and measured profiles).

In the prototype design 720, the rigid equivalent 710 has zero mobility. The parallel-jaw gripper would actuate by translating the finger base perpendicularly to the object. It has been shown that variable stiffness is advantageous for soft manipulators, and it is desirable to be able to grasp with both low and high stiffness. To achieve this with a single-DoF gripper, the force versus displacement curve was sculpted at the end effector so that it is relatively flat below a limiting displacement, at which the force ramps up. Note that because the rigid links form a parallelogram, the motion direction of the end effector is always horizontal and the vertical positioning of the force application point has no influence, facilitating experimental measurements. As for the example of FIGS. 6A-6F, the optimizer was able to find a link shape closely satisfying the targets. Good agreement was obtained with simulation on the fabricated prototype, except for the low-force region in which elasticity forces are too low to overcome friction at the joints thus violating static equilibrium. Note, however, that this does not interfere with the intended functionality of the finger.

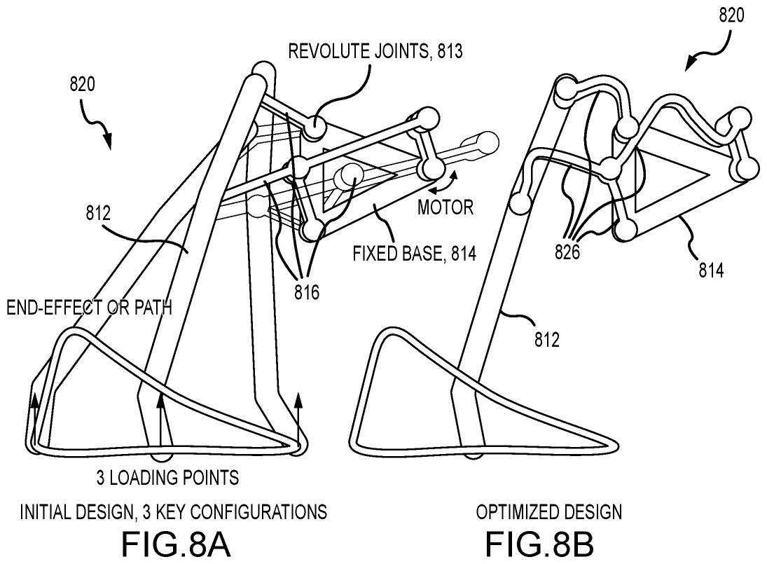

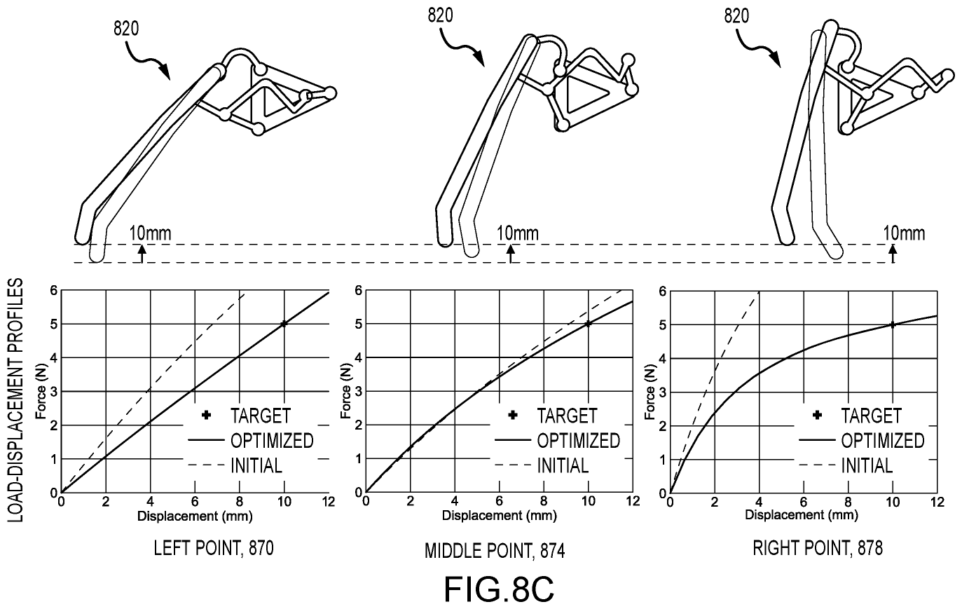

For any vehicle traversing uneven ground, suspension is essential. In an additional prototype of the new design process shown in FIGS. 8A-8C, the leg mechanism of a walking robot, based on the Klann linkage, was augmented with suspension. To this end, the initial robot mechanism 810 included an end effector 812 and a plurality of rigid links 816 along with a fixed base 814, which were coupled with revolute joints 813. In the optimized design of the flexible-link mechanism 820 the set of links 816 are replaced with flexible links 826 whose shapes are optimized as described herein such that all the links of the mechanism 820 except for the base 814 and end effector 812 were compliant, and force-displacement characteristics as shown in graphs 870, 874, and 878 in FIG. 8C were computed in simulation with the material parameters of Onyx.

In this protype example, a vertical displacement of the end effector 812 was set by a user-selected or set obstacle size (10 mm in this example) corresponding with a force (5 N in this example) sufficient to pull up the weight of the robot mechanism 820. The rational used is that a single leg hitting an obstacle before the others hit the ground should be able to lift the robot's weight. As shown in FIGS. 8A-8C, the optimizer was able to solve this problem instance. Note that, while only one target point on the load-displacement curve was considered, the problem is non-trivial as the same profile is desired for three different mechanism configurations, sampled on the ground section of the leg motion cycle. This example also illustrates the benefits of decoupling forces and motions during design because a mechanism with a desired motion cycle can be first designed using kinematic solvers and the kinematics-preserving method thought herein can then solve for the force-displacement profile.

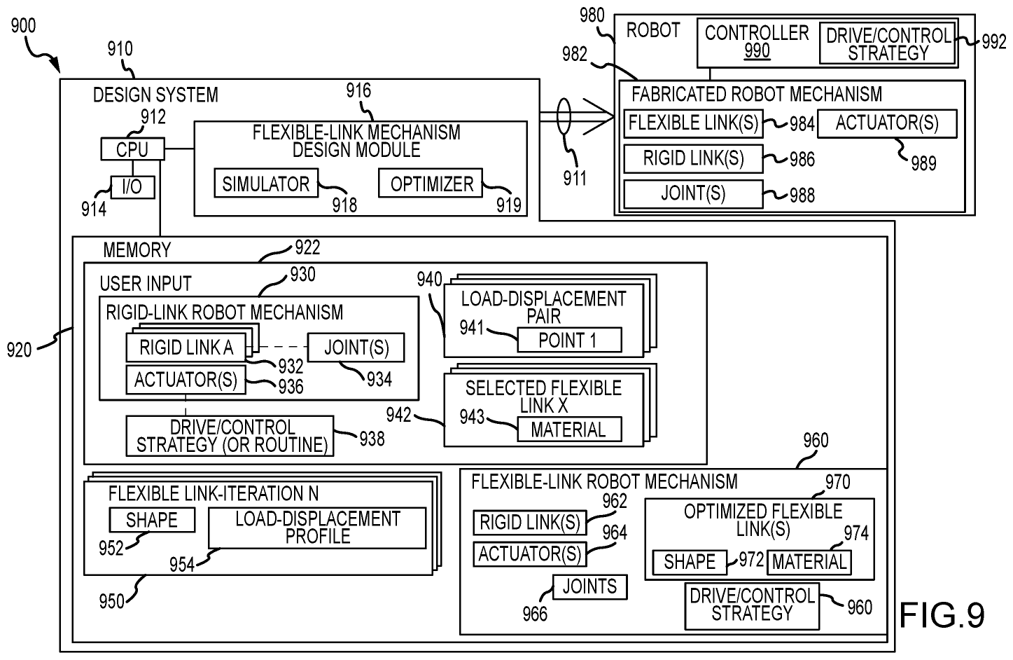

FIG. 9 is a functional block diagram of a robot fabrication system 900 with a design system 910 configured for implementing software and hardware to provide the simulation and optimization methods or functions described herein. To this end, the design system 910 (e.g., a computer or computing system) includes a processor 912 that manages access to and from memory (or data storage device(s)) 920 (which may be local or remote to the processor 912). The processor 912 also manages operations of one or more user input and output devices 914, which may be operated by a human operator or user (not shown) to enter user input 922 shown stored in memory 920 and to selectively cause an output file 911 to be generated for use in fabricating one or more robot mechanisms 982 of a physical robot 980. Particularly, the output 911 may include a definition or file associated with a flexible-link robot mechanism 960 generated during operations of the design system 910.

The processor 912 executes code or instructions (e.g., software or a computer program) to provide a flexible-link mechanism design module 916 and, particularly, the functionality of a simulator 918 and an optimizer 919. The simulator 918 is configured to implement the simulation methods or processes (or algorithms) described above while the optimizer 919 is configured to implement the optimization methods or processes (or algorithms) described above.

As input 922 to the module 916, a user of the system 910 may input or select a design or definition for a rigid-link robot mechanism 930 including the number and configuration of its rigid links 932, joints 934, and actuators 936 (e.g., motors, drivers, and the like). Also, the user may provide as input 922 a driver or control strategy (or routine) 932 for imparting movement(s) of the links 932 via the operation of the actuators 936. As part of the design process, the user further provides as input 922 a selection of one or more of the rigid links 932 to be replaced with a flexible link 942, along with a material or material parameters 943 for the to-be-optimized link 942. Additionally, the user input 922 will include load-displacement pairs 940 for the new flexible-link robot mechanism for one or more points on the links 932, 942 (or “configurations”, as discussed above).

As part of operations of the simulator 918 and optimizer 919, one-to-many iterations are performed for the flexible link as shown at 950 beginning with an initial shape and proceeding to an optimized shape 952 and with load-displacement profiles 954 being generated for each iteration. The optimizer 919 acts to compare the profile 954 with a target profile (from the load-displacement pairs 940), and, based on this comparison and other factors (as discussed above), modifies the shape 952 of the link 950 for a next iteration or run through the simulator 918. The output of the design module 916 is shown with file 960 and includes definitions (and configurations) of the rigid links 962 not replaced by flexible links from mechanism 930 along with the joints 966, actuators 964, and drive/control strategy 968 from the definition of the input robot mechanism 930. Further, and significantly, the definition/configuration of one or more optimized flexible links 970 are included in the definition/data file for the robot mechanism 960, including the optimized shape 972 and user-selected material 974.

This file 960 can then be used in the system 900 as shown at 911 to fabricate a flexible-link robot mechanism 982 for use or inclusion in a physical robot 980. The mechanism 982 includes rigid links 986, joints 988, and actuators 989 as defined for the mechanism 960 (and for the input mechanism 930 if not replaced by a flexible link) but also one or more flexible or compliant links 984 with the optimized shape defined at 972. The robot 980 includes a controller 990 for communicating control signals to the actuators 989 to provide the desired movements/actions of the mechanism 982 according to a drive or control strategy (or routine) 992 matching or based on the initial user input drive/control strategy 938, while the “intelligence” of the mechanism 982 provided by the inclusion of the flexible link(s) 984 allows operation over a range at one or more user-selected points of interest on the robot mechanism 982.

Although the invention has been described and illustrated with a certain degree of particularity, it is understood that the present disclosure has been made only by way of example, and that numerous changes in the combination and arrangement of parts can be resorted to by those skilled in the art without departing from the spirit and scope of the invention, as hereinafter claimed.

In the foregoing description, a method was described for the optimization of load-displacement profiles of flexible-link robot mechanisms, providing several demonstrations that illustrate its utility and applications. In initial testing and prototyping, the simulator and optimizer were implemented in C++. Computations were performed on a machine with an Intel Core i7-7700 processor (4 cores, 4.2 GHz) and 32 GB of RAM, with 39 to 138 iterations being required at operational times in the range of about 2.5 hours to 9.5 hours.

We claim:

1. A method for optimizing a design of a robot mechanism including rigid and flexible links, comprising:
with a computing device, receiving user input including a definition of a robot mechanism with a plurality of rigid links, one or more joints coupling the rigid links, and one or more actuators for driving movement of the rigid links, wherein the user input further includes a selection of one or more of the rigid links for replacement with flexible links;
with a simulator running on the computing device, simulating operation of the robot mechanism with the flexible link; and
with an optimizer running on the computing device, comparing the simulated operation of the robot mechanism to user-defined operations of the robot mechanism;
based on the comparing, modifying the shape of the flexible links; and
optimizing the shape of the flexible links by repeating the simulating and the comparing steps.

2. The method of claim 1, wherein the user-defined operations comprise load-displacement samples for one or more points of interest on the robot mechanism.

3. The method of claim 2, wherein the simulating operation comprises setting the one or more actuators to a particular configuration and forces to user-specified forces in the load-displacement samples.

4. The method of claim 2, wherein comparing the simulated operation comprises comparing simulated displacements from the simulating operation to user-specified displacements in the load-displacement samples.

5. The method of claim 1, wherein the definition of the robot mechanism further comprises a user selection of a material to be assigned to the flexible link for the simulating operation.

6. The method of claim 1, wherein the simulator comprises a differentiable quasi-static simulator.

7. The method of claim 6, wherein the differentiable quasi-static simulator is configured to enforce coupling between flexible-flexible and flexible-rigid link pairs in the robot mechanism after inclusion of the flexible links using constraints in a Lagrangian formulation.

8. The method of claim 1, wherein the repeating is performed until the comparing indicates a match between the simulated operation and a load-displacement profile at user-specified points of interest on the robot mechanism.

9. The method of claim 1, wherein the simulating operation comprises performing a smooth remeshing-free parameterization of a volumetric rest shape of the flexible links using splines.

10. The method of claim 1, wherein the shape is an at rest configuration of the flexible links.

11. A robot mechanism fabricated based on the definition of the robot mechanism of claim 1 and including one or more flexible links fabricated based on the optimized shape generated by performance of the method of claim 1.

12. A method for optimizing a design of a robot mechanism including rigid and flexible links, comprising:
with a computing device, accessing user input including a definition of a robot mechanism with a plurality of rigid links, wherein the user input further includes a selection of one or more of the rigid links for replacement with flexible links and load-displacement samples for one or more points of interest on the robot mechanism;
with a simulator running on a computing device, simulating operation of the robot mechanism with the flexible links; and
with an optimizer running on the computing device, comparing the simulated operation of the robot mechanism to the load-displacement samples of the robot mechanism; and
based on the comparing, modifying the shape of the flexible links with the optimizer, wherein the shape is the rest configuration of the flexible links.

13. The method of claim 12, wherein the simulating operation comprises setting one or more actuators of the robot mechanism to a particular configuration and forces to user-specified forces in the load-displacement samples.

14. The method of claim 12, wherein the comparing the simulated operation comprises comparing simulated displacements from the simulating operation to user-specified displacements in the load-displacement samples.

15. The method of claim 12, wherein the simulator comprises a differentiable quasi-static simulator.

16. The method of claim 15, wherein the differentiable quasi-static simulator is configured to enforce coupling between flexible-flexible and flexible-rigid link pairs in the robot mechanism after inclusion of the flexible links using constraints in a Lagrangian formulation.

17. The method of claim 12, further comprising optimizing the shape of the flexible links by repeating the simulating, the comparing, and the modifying until the comparing indicates a match between the simulated operation and a load-displacement profile at user-specified points of interest on the robot mechanism.

18. The method of claim 12, wherein the simulating operation comprises performing a smooth remeshing-free parameterization of a volumetric rest shape of the flexible links using splines.

19. A system for designing a robot mechanism with rigid links and at least one compliant link, comprising:
memory storing user input including a definition of a robot mechanism with a plurality of rigid links, one or more joints coupling the rigid links, and one or more actuators for driving movement of the rigid links, wherein the user input further includes a selection of one or more of the rigid links for replacement with flexible links;
a simulator provided by a processor executing code or instructions and configured to simulate operation of the robot mechanism with the flexible links; and
an optimizer provided by a processor executing code or instructions and configured to compare the simulated operation of the robot mechanism to user-defined operations of the robot mechanism and to modify an at-rest configuration of the flexible links.

20. The system of claim 19, wherein the user-defined operations comprises load-displacement samples for one or more points of interest on the robot mechanism, wherein the simulating operation comprises setting the one or more actuators to a particular configuration and forces to user-specified forces in the load-displacement samples, and wherein the comparing the simulated operation comprises comparing simulated displacements from the simulating operation to user-specified displacements in the load-displacement samples.

21. The system of claim 19, wherein the simulator comprises a differentiable quasi-static simulator.

22. The system of claim 21, wherein the differentiable quasi-static simulator is configured to enforce coupling between flexible-flexible and flexible-rigid link pairs in the robot mechanism after inclusion of the flexible links using constraints in a Lagrangian formulation.

23. The system of claim 19, wherein the simulating operation comprises performing a smooth remeshing-free parameterization of the volumetric rest shape of the flexible links using splines.
